(19) United States
(12) Patent Application Publication
(10) Pub. No.: US 2024/0355760 A1
(43) Pub. Date: Oct. 24, 2024

(54) Semiconductor Device and Method of Forming Stress Relief Vias in Multi-Layer RDL

(71) Applicant: STATS ChipPAC Pte. Ltd., Singapore (SG)

(72) Inventors: Peik Eng Ooi, Singapore (SG); Gai Leong Lai, Singapore (SG)

(73) Assignee: STATS ChipPAC Pte. Ltd., Singapore (SG)

(21) Appl. No.: 18/302,503

(22) Filed: Apr. 18, 2023

(51) Int. Cl. H01L 23/00

(52) U.S. Cl. CPC H01L 23/562; H01L 24/19; H01L 24/20; H01L 2224/19; H01L 2224/2105; H01L 2224/214; H01L 2224/215; H01L 2924/01013; H01L 2924/01028; H01L 2924/01029; H01L 2924/01047; H01L 2924/0105; H01L 2924/01079

(57) ABSTRACT

A semiconductor device has a substrate and a first RDL formed over the substrate. A second RDL is formed over the first RDL with a first conductive via electrically connecting the first RDL and second RDL and a first opening formed in the second RDL around the first conductive via for stress relief. The first opening formed in the second RDL can have a semi-circle shape or a plurality of semi-circles or segments. A third RDL is formed over the second RDL with a second conductive via electrically connecting the second RDL and third RDL and a second opening formed in the third RDL around the second conductive via for stress relief. The first opening is offset from the second opening. A plurality of first openings can be formed around the first conductive via for stress relief, each offset from one another.

### FIELD OF THE INVENTION

The present invention relates in general to semiconductor devices and, more particularly, to a semiconductor device and method of forming vias to reduce stress, delamination, and warpage in multi-layer RDL.

### BACKGROUND OF THE INVENTION

Semiconductor devices are commonly found in modern electrical products. Semiconductor devices perform a wide range of functions, such as signal processing, high-speed calculations, transmitting and receiving electromagnetic signals, controlling electrical devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices often contain a semiconductor die or substrate with electrical interconnect structures, e.g., redistribution layers (RDL) formed over one or more surfaces of the semiconductor die or substrate to perform necessary electrical functions. The semiconductor devices are formed wafer or panels during the manufacturing process. The wafer and panels are subject to cracking due to the propagation of thermal stress, delamination, and warping displacement contributed by one or more expansive metal layers during formation of the RDL. Larger fan-out devices have a higher risk of cracking and consequently, lower yield leading to higher manufacturing costs.

### BRIEF DESCRIPTION OF THE DRAWINGS

FIGS. 1a-1c illustrate a semiconductor wafer with a plurality of semiconductor die separated by a saw street;

FIGS. 2a-2d illustrate a process of depositing encapsulant over a semiconductor die as a reconstituted WLP;

FIGS. 3a-3f illustrate a process of forming multi-layer RDL on the reconstituted WLP;

FIGS. 4a-4d illustrate a top view of the stress relief vias in the RDL;

FIG. 5 illustrates another embodiment of the multi-layer RDL on the reconstituted WLP;

FIGS. 6a-6e illustrate another embodiment of the stress relief vias in the RDL;

FIG. 7 illustrates another embodiment of the multi-layer RDL on the reconstituted WLP;

FIGS. 8a-8d illustrate another embodiment of the stress relief vias in the RDL;

FIG. 9 illustrates another embodiment of the multi-layer RDL on the reconstituted WLP;

FIGS. 10a-10d illustrate another embodiment of the stress relief vias in the RDL; and

FIG. 11 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements having a similar function are assigned the same reference number in the figures. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

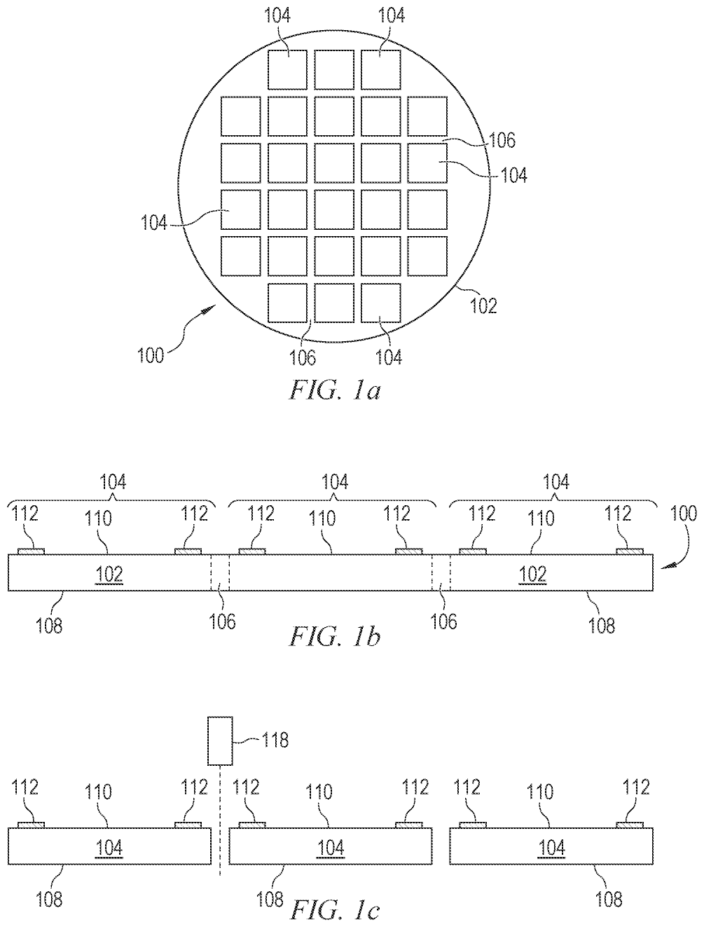

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die or known good unit (KGD/KGU) post singulation.

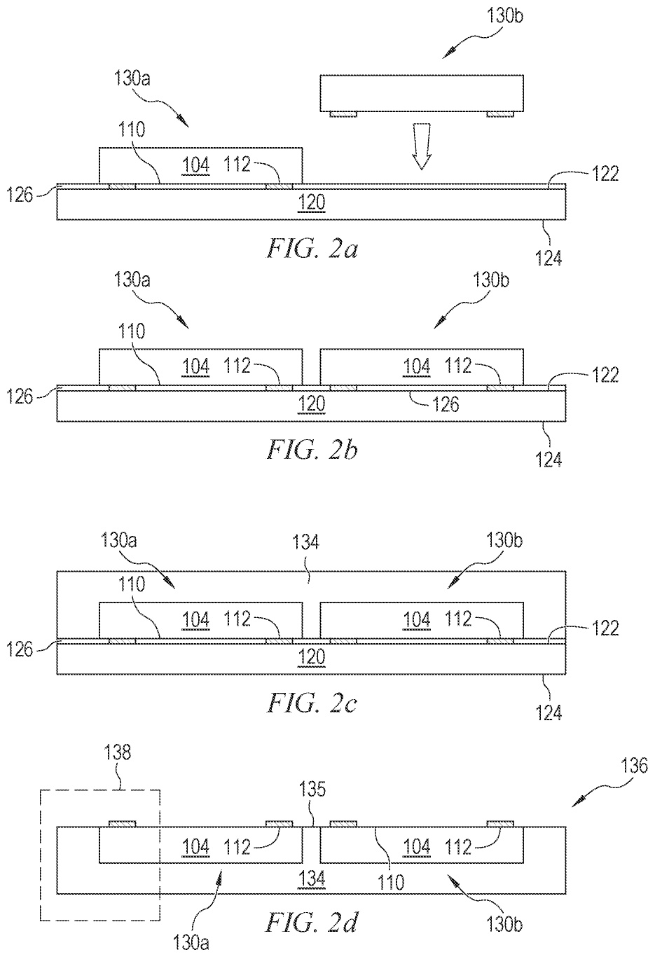

FIG. 2a shows a temporary substrate or carrier 120 sacrificial base material such as silicon, polymer, beryllium oxide, glass, or other suitable low-cost, rigid material for structural support. Substrate 120 has major surfaces 122 and 124. In one embodiment, carrier 120 is a support structure with a temporary bonding layer 126.

Electrical components 130a-130b are disposed on surface 122 of substrate 120. Electrical components 130a and 130b can be similar to, or made similar to, semiconductor die 104 from FIG. 1c with conductive layer 112 oriented toward surface 122 of substrate 120. Alternatively, electrical components 130a-130b can include other semiconductor die, semiconductor packages, surface mount devices, RF components, discrete electrical devices, or integrated passive devices (IPD).

Electrical components 130a-130b are positioned over substrate 120 using a pick and place operation. Electrical components 130a-130b are brought into contact with bonding layer 126. FIG. 2b illustrates electrical components 130a-130b bonded to substrate 120, as a reconstituted wafer level package (WLP).

In FIG. 2c, encapsulant or molding compound 134 is deposited over and around electrical components 130a-130b and substrate 120 using a paste printing, compressive molding, transfer molding, liquid encapsulant molding, vacuum lamination, spin coating, or other suitable applicator. Encapsulant 134 can be liquid or granular polymer composite material, such as epoxy resin with filler, epoxy acrylate with filler, or polymer with proper filler. Encapsulant 134 is non-conductive, provides structural support, and environmentally protects the semiconductor device from external elements and contaminants.

In FIG. 2d, carrier 120 and bonding layer 126 are removed by chemical etching, chemical mechanical polishing (CMP), mechanical peel-off, mechanical grinding, thermal bake, ultra-violet (UV) light, or wet stripping to expose surface 110 and conductive layer 112. Semiconductor assembly 136 is ready for a multi-layer RDL buildup structure on surface 135 of encapsulant 134 and conductive layer 112 of semiconductor die 104 to provide electrical interconnect for the semiconductor die, as well as external electrical components. Semiconductor assembly 136 operates as a substrate to form the multi-layer RDL buildup structure.

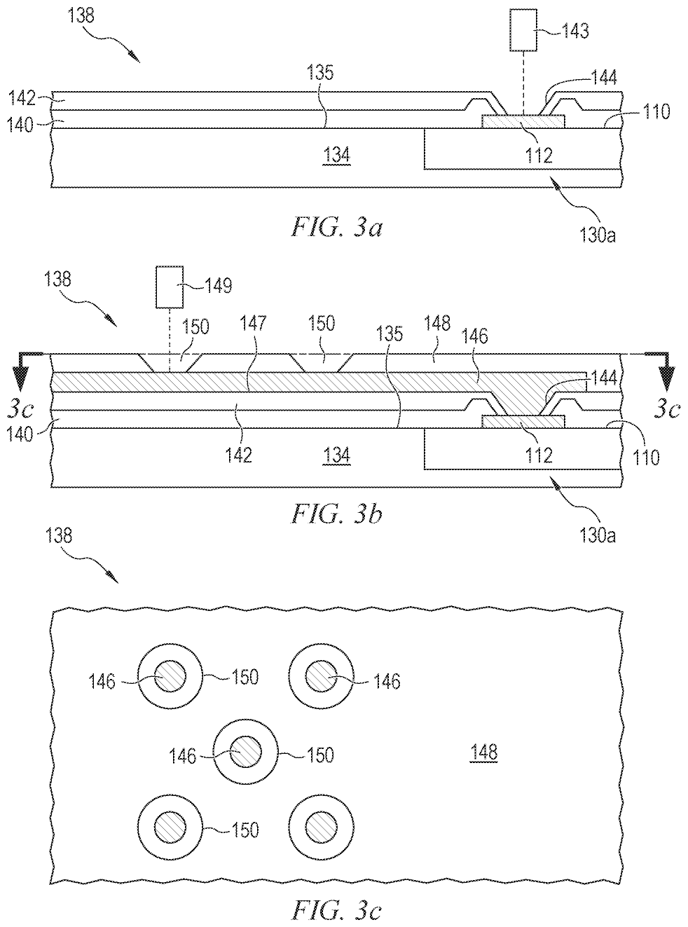

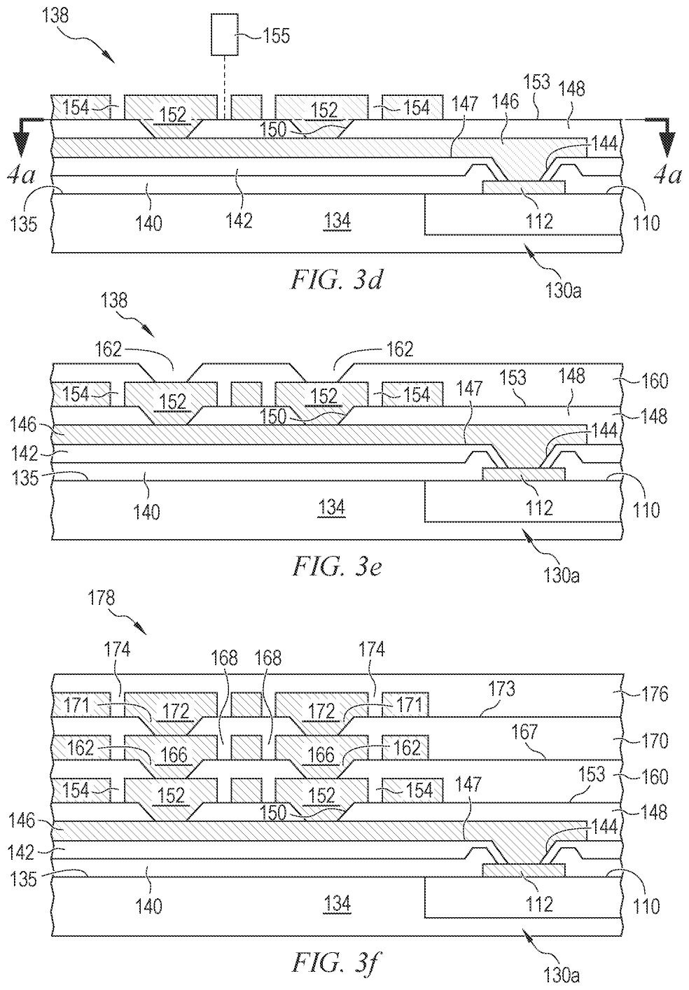

FIGS. 3a-3f focus on box or region 138 of semiconductor assembly 136. In FIG. 3a, insulating or passivation layer 140 is formed over surface 135 and surface 110 and conductive layer 112 using PVD, CVD, printing, lamination, spin coating, spray coating, sintering or thermal oxidation. Insulating layer 140 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties.

An insulating or passivation layer 142 is formed over insulating layer 140 using PVD, CVD, printing, lamination, spin coating, spray coating, sintering or thermal oxidation. Insulating layer 142 contains one or more layers of SiO2, Si3N4, SiON, Ta2O5, Al2O3, solder resist, polyimide, BCB, PBO, and other material having similar insulating and structural properties. Portions of insulating layers 140 and 142 are removed using an etching process or laser direct ablation (LDA) using laser 143 to form openings or vias 144 extending to conductive layer 112 for further electrical interconnect, such as multi-layer RDL buildup structures.

In FIG. 3b, conductive layer 146 is formed over surface 147 of insulating layer 142 and into vias 144 using PVD, CVD, electrolytic plating, electroless plating process, or other suitable metal deposition process. Conductive layer 146 can be one or more layers of Al, Cu, Sn, Ni, Au, Ag, or other suitable electrically conductive material. Conductive layer 146 is an RDL as it redistributes the electrical signal across and over semiconductor die 104 and encapsulant 134. Portions of conductive layer 146 can be electrically common or electrically isolated depending on the design and function of semiconductor die 104 and other electrical components attached thereto.

An insulating or passivation layer 148 is formed over insulating layer 142 and conductive layer 146 using PVD, CVD, printing, lamination, spin coating, spray coating, sintering or thermal oxidation. Insulating layer 148 contains one or more layers of SiO2, Si3N4, SiON, Ta2O5, Al2O3, solder resist, polyimide, BCB, PBO, and other material having similar insulating and structural properties. Portions of insulating layer 148 are removed using an etching process or LDA using laser 149 to form openings or vias 150 extending to conductive layer 146 for further electrical interconnect, such as multi-layer RDL buildup structures. Insulating layers 142 and 148 provide isolation around conductive layer 146. FIG. 3c is a top view of vias 150 extending through insulating layer 148 to conductive layer 146.

In FIG. 3d, conductive layer 152 is formed over surface 153 of insulating layer 148 and into vias 150 using PVD, CVD, electrolytic plating, electroless plating process, or other suitable metal deposition process. Conductive layer 152 can be one or more layers of Al, Cu, Sn, Ni, Au, Ag, or other suitable electrically conductive material. Conductive layer 152 is an RDL as it redistributes the electrical signal across and over semiconductor die 104, encapsulant 134, and conductive layer 146. Portions of conductive layer 152 can be electrically common or electrically isolated depending on the design and function of semiconductor die 104 and other electrical components attached thereto. Portions of conductive layer 152 are removed using an etching process or LDA using laser 155 to form stress relief openings or vias or slots 154 extending at least partially around that portion of conductive layer 152 within via 150 and further extending to insulating layer 148. Vias 154 reduce or eliminate cracking of conductive layer 152 due to stress, delamination, and warpage.

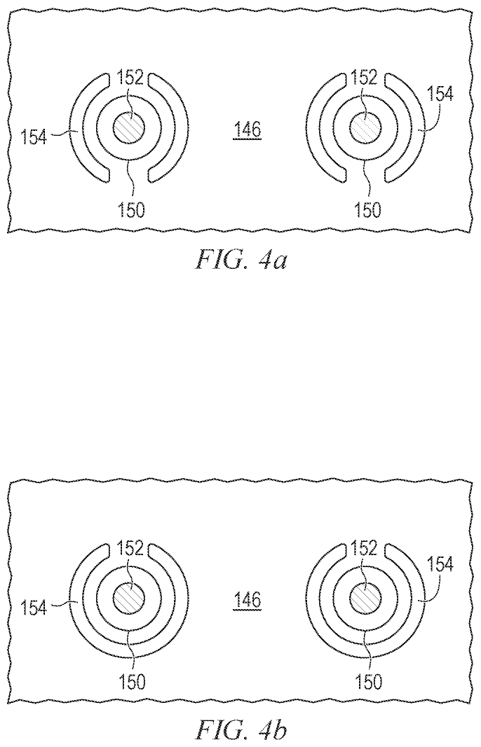

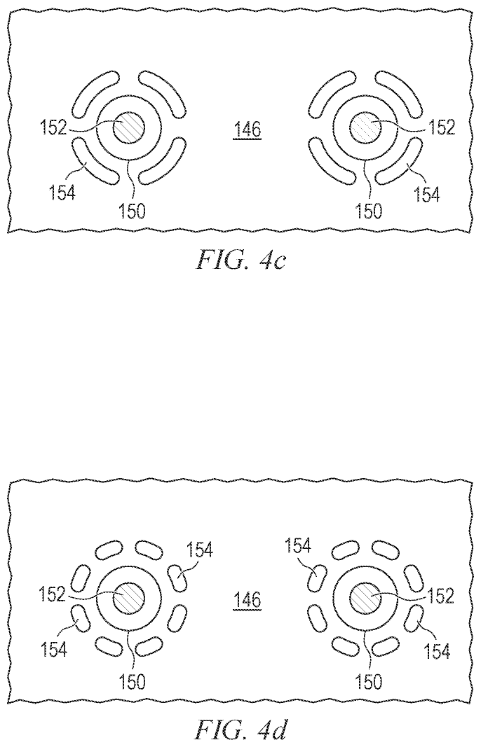

FIG. 4a is a top view of a first embodiment of vias 154 formed at least partially around that portion of conductive layer 152 within via 150. In the first embodiment, vias 154 are partial arcs or segments on opposite sides of vias 150. FIG. 4b is a top view of a second embodiment of vias 154 formed at least partially around that portion of conductive layer 152 within via 150. In the second embodiment, via 154 is a partial circle around via 150. FIG. 4c is a top view of a third embodiment of vias 154 formed at least partially around that portion of conductive layer 152 within via 150. In the third embodiment, vias 154 are partial arcs or segments on four sides of via 150. FIG. 4d is a top view of a fourth embodiment of vias 154 formed at least partially around that portion of conductive layer 152 within via 150. In the fourth embodiment, vias 154 are partial segments around vias 150.

Returning to FIG. 3e, insulating or passivation layer 160 is formed over surface 153 of insulating layer 148 and conductive layer 152 using PVD, CVD, printing, lamination, spin coating, spray coating, sintering or thermal oxidation. Insulating layer 160 contains one or more layers of SiO2, Si3N4, SiON, Ta2O5, Al2O3, solder resist, polyimide, BCB, PBO, and other material having similar insulating and structural properties. Portions of insulating layer 148 are removed using an etching process or LDA, similar to FIG. 3b, to form openings or vias 162 extending to conductive layer 152 for further electrical interconnect, such as multi-layer RDL buildup structures. Insulating layers 148 and 160 provide isolation around conductive layer 152.

In FIG. 3f, conductive layer 166 is formed over surface 167 of insulating layer 160 and into vias 162 using PVD, CVD, electrolytic plating, electroless plating process, or other suitable metal deposition process. Conductive layer 166 can be one or more layers of Al, Cu, Sn, Ni, Au, Ag, or other suitable electrically conductive material. Conductive layer 166 is an RDL as it redistributes the electrical signal across and over semiconductor die 104, encapsulant 134, and conductive layer 152. Portions of conductive layer 166 can be electrically common or electrically isolated depending on the design and function of semiconductor die 104 and other electrical components attached thereto. Portions of conductive layer 162 are removed using an etching process or LDA, similar to FIG. 3d, to form stress relief openings or vias or slots 168 extending at least partially around that portion of conductive layer 166 within via 162 and further extending to insulating layer 160. Vias 168 reduce or eliminate cracking of conductive layer 166 due to stress, delamination, and warpage. A top view of vias 168 is similar to FIGS. 4a-4d.

An insulating or passivation layer 170 is formed over surface 167 of insulating layer 160 and conductive layer 166 using PVD, CVD, printing, lamination, spin coating, spray coating, sintering or thermal oxidation. Insulating layer 170 contains one or more layers of SiO2, Si3N4, SiON, Ta2O5, Al2O3, solder resist, polyimide, BCB, PBO, and other material having similar insulating and structural properties. Portions of insulating layer 170 are removed using an etching process or LDA, similar to FIG. 3b, to form openings or vias 171 extending to conductive layer 166 for further electrical interconnect, such as multi-layer RDL buildup structures. Insulating layers 160 and 170 provide isolation around conductive layer 166.

A conductive layer 172 is formed over surface 173 of insulating layer 170 and into vias 171 using PVD, CVD, electrolytic plating, electroless plating process, or other suitable metal deposition process. Conductive layer 172 can be one or more layers of Al, Cu, Sn, Ni, Au, Ag, or other suitable electrically conductive material. Conductive layer 172 is an RDL as it redistributes the electrical signal across and over semiconductor die 104, encapsulant 134, and conductive layer 166. Portions of conductive layer 172 can be electrically common or electrically isolated depending on the design and function of semiconductor die 104 and other electrical components attached thereto. Portions of conductive layer 172 are removed using an etching process or LDA, similar to FIG. 3d, to form stress relief openings or vias or slots 174 extending at least partially around that portion of conductive layer 172 within via 171 and further extending to insulating layer 170. Vias 174 reduce or eliminate cracking of conductive layer 172 due to stress, delamination, and warpage. A top view of vias 174 is similar to FIGS. 4a-4d.

An insulating or passivation layer 176 is formed over surface 173 of insulating layer 170 and conductive layer 172 using PVD, CVD, printing, lamination, spin coating, spray coating, sintering or thermal oxidation. Insulating layer 176 contains one or more layers of SiO2, Si3N4, SiON, Ta2O5, Al2O3, solder resist, polyimide, BCB, PBO, and other material having similar insulating and structural properties. Insulating layers 170 and 176 provide isolation around conductive layer 172.

WLP 178 has multiple conductive layers 152, 166, and 172 constituting a multi-layer RDL structure. The stress relief vias 154, 168, and 174 reduce or eliminate cracking in the multi-layer RDL caused by stress, delamination, and warpage. The stress relief vias 154, 168, and 174 are formed around the conductive vias between each RDL layer. The inter-RDL connecting vias, such as vias 144, 150, 162, and 171, are likely points of cracking due to stress, delamination, and warpage. Vias 154, 168, and 174 result in less metal coverage and more points of stress relief for WLP 178. The multi-circular design in FIGS. 4a-4d provide more cutouts compared to single circular design, hence reduced metal density further to improve the stress, delamination and warpage issues.

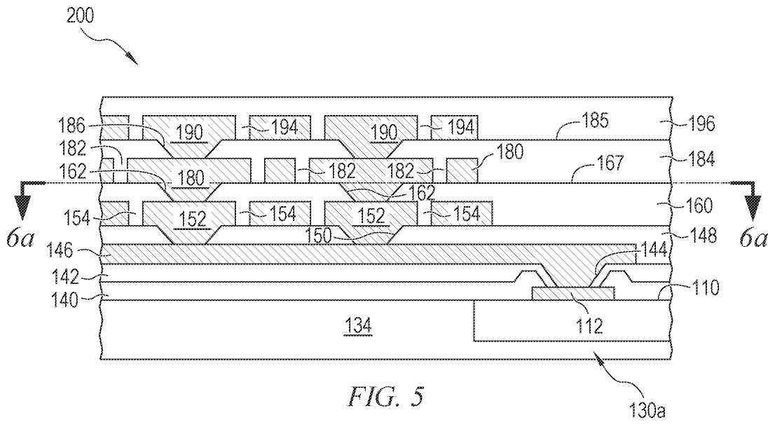

In another embodiment, continuing from FIG. 3e, conductive layer 180 is formed over surface 167 of insulating layer 160 and into vias 162 using PVD, CVD, electrolytic plating, electroless plating process, or other suitable metal deposition process, as shown in FIG. 5. Conductive layer 180 can be one or more layers of Al, Cu, Sn, Ni, Au, Ag, or other suitable electrically conductive material. Conductive layer 180 is an RDL as it redistributes the electrical signal across and over semiconductor die 104, encapsulant 134, and conductive layer 152. Portions of conductive layer 180 can be electrically common or electrically isolated depending on the design and function of semiconductor die 104 and other electrical components attached thereto. Portions of conductive layer 180 are removed using an etching process or LDA, similar to FIG. 3d, to form stress relief openings or vias or slots 182 extending at least partially around that portion of conductive layer 180 within via 162 and further extending to insulating layer 160. Notably, vias 182 in conductive layer 180 are offset or spaced apart from vias 154 in that vias 154 are formed closer to vias 150 and vias 182 are formed farther away from the center of vias 150, as compared to vias 154. Vias 182 reduce or eliminate cracking of conductive layer 180 due to stress, delamination, and warpage.

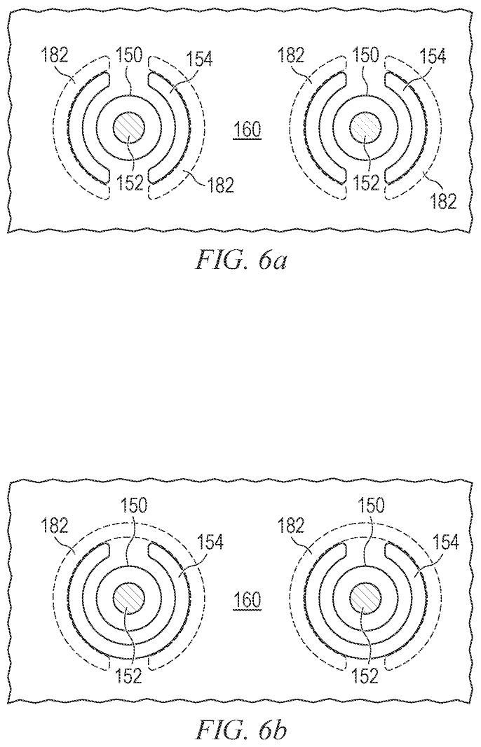

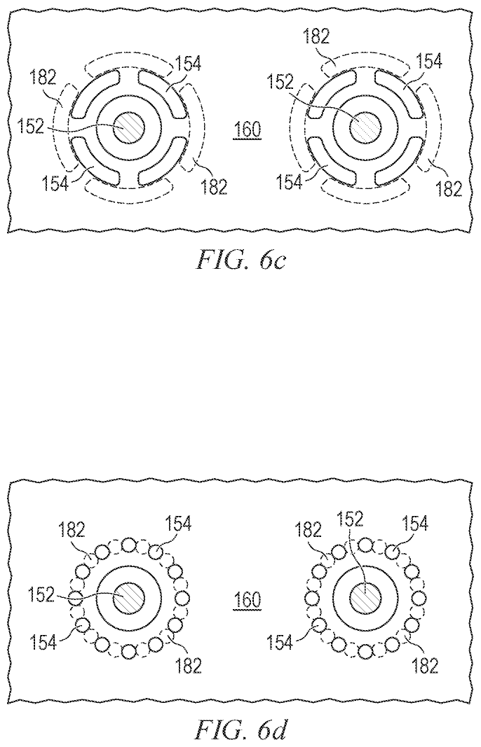

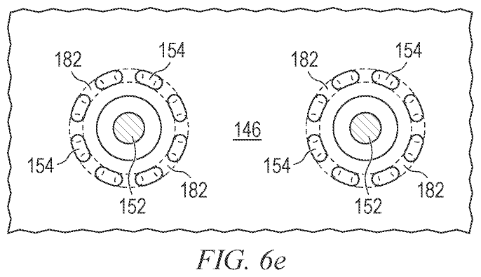

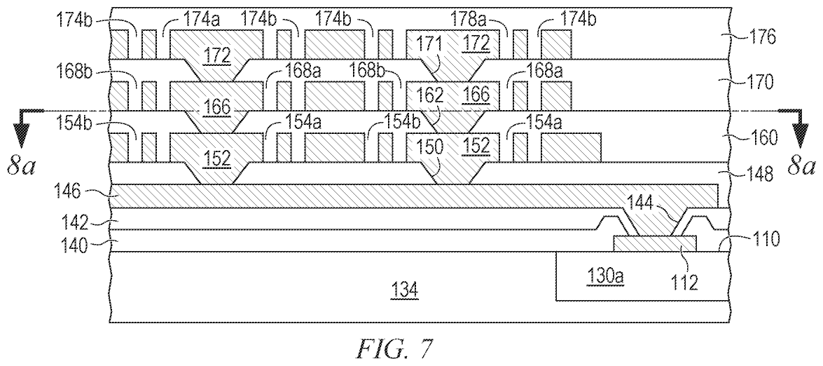

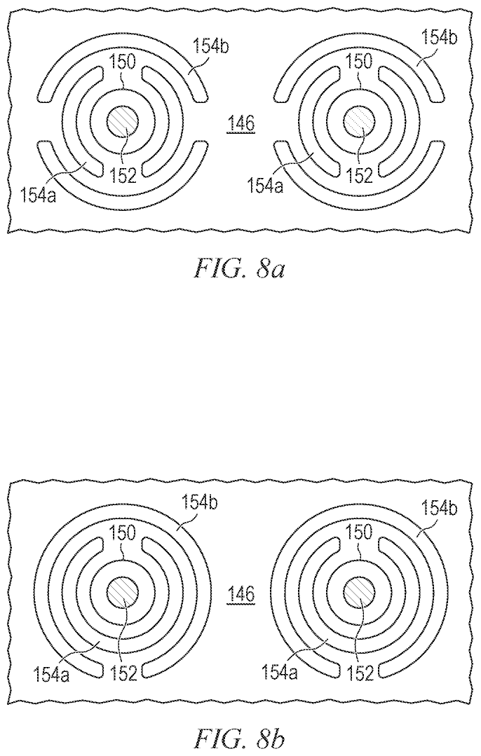

FIG. 6a is a top view of a first embodiment of vias 182 formed at least partially around and offset or spaced away from vias 154. In the first embodiment, vias 182 are partial arcs or segments on opposite sides of and offset or spaced away from vias 154. FIG. 6b is a top view of a second embodiment of vias 182 formed at least partially around and offset or spaced away from vias 154. In the second embodiment, via 182 is a partial circle around and offset or spaced away from via 154. FIG. 6c is a top view of a third embodiment of vias 182 formed at least partially around and offset or spaced away from via 154. In the third embodiment, vias 182 are partial arcs or segments on four sides of and offset or spaced away from vias 154. FIG. 6d is a top view of a fourth embodiment of vias 182 formed in between vias 154. In the fourth embodiment, vias 154 are partial segments in between vias 154. FIG. 6e is a top view of a fifth embodiment of vias 182 formed in between vias 154. In the fifth embodiment, vias 154 are partial segments in between vias 154.

Returning to FIG. 5, insulating or passivation layer 184 is formed over surface 167 of insulating layer 160 and conductive layer 180 using PVD, CVD, printing, lamination, spin coating, spray coating, sintering or thermal oxidation. Insulating layer 184 contains one or more layers of SiO2, Si3N4, SiON, Ta2O5, Al2O3, solder resist, polyimide, BCB, PBO, and other material having similar insulating and structural properties. Portions of insulating layer 184 are removed using an etching process or LDA, similar to FIG. 3b, to form openings or vias 186 extending to conductive layer 180 for further electrical interconnect, such as multi-layer RDL buildup structures. Insulating layers 160 and 184 provide isolation around conductive layer 180.

A conductive layer 190 is formed over surface 185 of insulating layer 184 and into vias 186 using PVD, CVD, electrolytic plating, electroless plating process, or other suitable metal deposition process. Conductive layer 190 can be one or more layers of Al, Cu, Sn, Ni, Au, Ag, or other suitable electrically conductive material. Conductive layer 190 is an RDL as it redistributes the electrical signal across and over semiconductor die 104, encapsulant 134, and conductive layer 180. Portions of conductive layer 190 can be electrically common or electrically isolated depending on the design and function of semiconductor die 104 and other electrical components attached thereto. Portions of conductive layer 190 are removed using an etching process or LDA, similar to FIG. 3d, to form stress relief openings or vias or slots 194 extending at least partially around that portion of conductive layer 190 within via 186 and further extending to insulating layer 184. Vias 194 reduce or eliminate cracking of conductive layer 190 due to stress, delamination, and warpage. A top view of vias 194 is similar to FIGS. 4a-4d.

An insulating or passivation layer 196 is formed over surface 185 of insulating layer 184 and conductive layer 190 using PVD, CVD, printing, lamination, spin coating, spray coating, sintering or thermal oxidation. Insulating layer 196 contains one or more layers of SiO2, Si3N4, SiON, Ta2O5, Al2O3, solder resist, polyimide, BCB, PBO, and other material having similar insulating and structural properties. Insulating layers 184 and 196 provide isolation around conductive layer 190.

WLP 200 has multiple conductive layers 152, 180, and 190 constituting a multi-layer RDL structure. The stress relief vias 154, 182, and 194 reduce or eliminate cracking in the multi-layer RDL caused by stress, delamination, and warpage. The stress relief vias 154, 182, and 194 are formed around the conductive vias between each RDL layer. The inter-RDL connecting vias, such as 144, 150, 162, and 186, are likely points of cracking due to stress, delamination, and warpage. Vias 154, 182, and 194 result in less metal coverage and more points of stress relief for WLP 200. The multi-circular design in FIGS. 4a-4d provide more cutouts compared to single circular design, hence reduced metal density further to improve the stress, delamination and warpage issues. Stress relief vias 154 and 194 are vertically aligned in conductive layers 152 and 190, while stress relief vias 182 in conductive layer 180 are offset or spaced apart from vias 154 and 194. Likewise, the multi-circular design has more Cu cutouts compared to single circular design, hence reduced Cu density further to improve the stress, delamination and warpage issues.

In another embodiment, FIG. 7 illustrates multiple stress relief vias for each conductive via. FIG. 7 is formed similar to FIGS. 3a-3f with stress relief vias 154a and 154b, 168a and 168b, and 174a and 174b. For example, vias 154b in conductive layer 152 are offset or spaced apart from vias 154a in that vias 154a are formed closer to vias 150 and vias 154b are formed farther away from the center of vias 150, as compared to vias 154a. In a similar manner, vias 168b in conductive layer 166 are offset or spaced apart from vias 168a in that vias 168a are formed closer to vias 162 and vias 168b are formed farther away from the center of vias 162, as compared to vias 168a. Vias 174b in conductive layer 172 are offset or spaced apart from vias 174a in that vias 174a are formed closer to vias 171 and vias 174b are formed farther away from the center of vias 171, as compared to vias 174a.

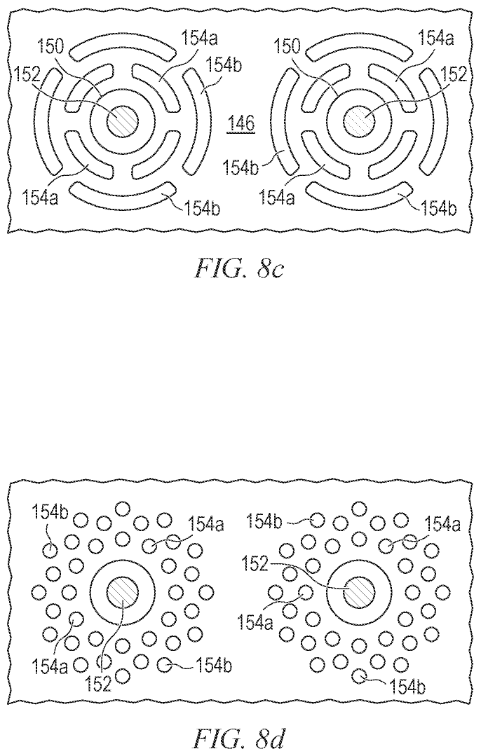

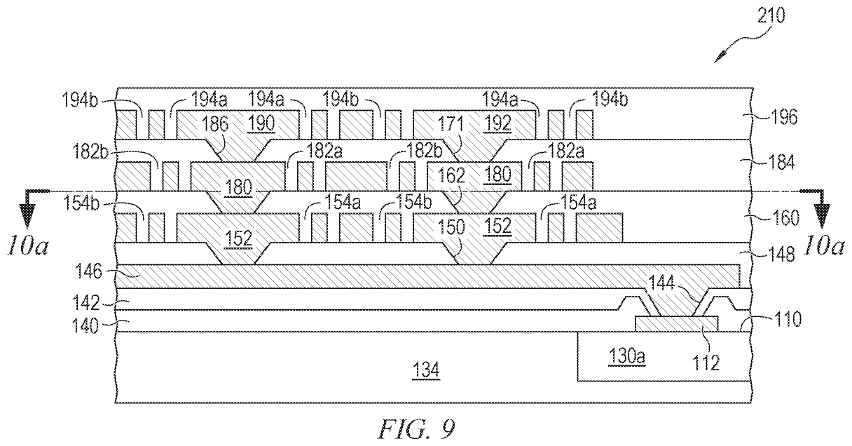

FIG. 8a is a top view of a first embodiment of vias 154a and 154b formed at least partially around that portion of conductive layer 152 within via 150. In the first embodiment, vias 154a and 154b are partial arcs or segments on opposite sides of via 150. Via 154b is offset or spaced apart from via 154a. FIG. 8b is a top view of a second embodiment of vias 154a and 154b formed at least partially around that portion of conductive layer 152 within via 150. In the second embodiment, via 154a and 154b are a partial circle around via 150. Via 154b is offset or spaced apart from via 154a. FIG. 8c is a top view of a third embodiment of vias 154a and 154b formed at least partially around that portion of conductive layer 152 within via 150. In the third embodiment, vias 154a and 154b are partial arcs or segments on four sides of via 150. Via 154b is offset or spaced apart from via 154a. FIG. 8d is a top view of a fourth embodiment of vias 154a and 154b formed at least partially around that portion of conductive layer 152 within via 150. In the fourth embodiment, vias 154a and 154b are partial segments around via 150. Via 154b is offset or spaced apart from via 154a. The top views of FIGS. 8a-8d are applicable to stress relief vias 168a and 168b and 174a and 174b.

In another embodiment, FIG. 9 illustrates multiple stress relief vias for each conductive via. The multiple stress relief vias are offset or spaced apart from one another. FIG. 9 is formed similar to FIG. 5 with additional stress relief vias 154a and 154b, 182a and 182b, and 194a and 194b. For example, vias 154b in conductive layer 152 are offset or spaced apart from vias 154a in that vias 154a are formed closer to vias 150 and vias 154b are formed farther away from the center of vias 150, as compared to vias 154a. Vias 182b in conductive layer 180 are offset or spaced apart from vias 182 in that vias 182a are formed closer to vias 162 and vias 182b are formed farther away from the center of vias 162, as compared to vias 18sa. In addition, vias 182a and 182b are offset or spaced apart from vias 154a and 154b. Vias 194b in conductive layer 190 are offset or spaced apart from vias 194a in that vias 194a are formed closer to vias 186 and vias 194b are formed farther away from the center of vias 186, as compared to vias 194a. In addition, vias 194a and 184b are offset or spaced apart from vias 182a and 182b.

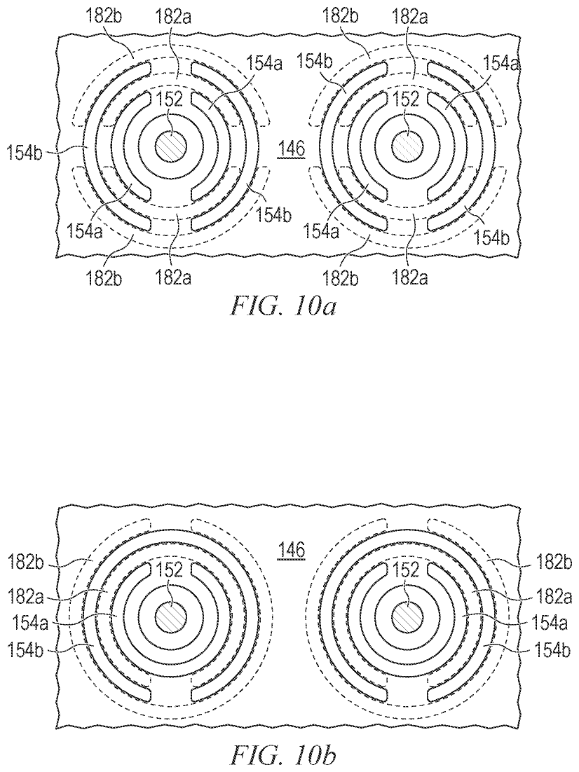

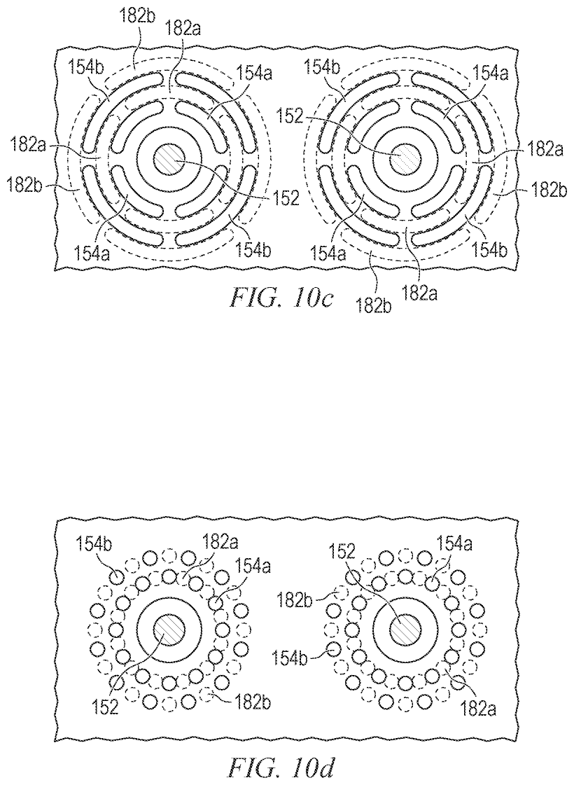

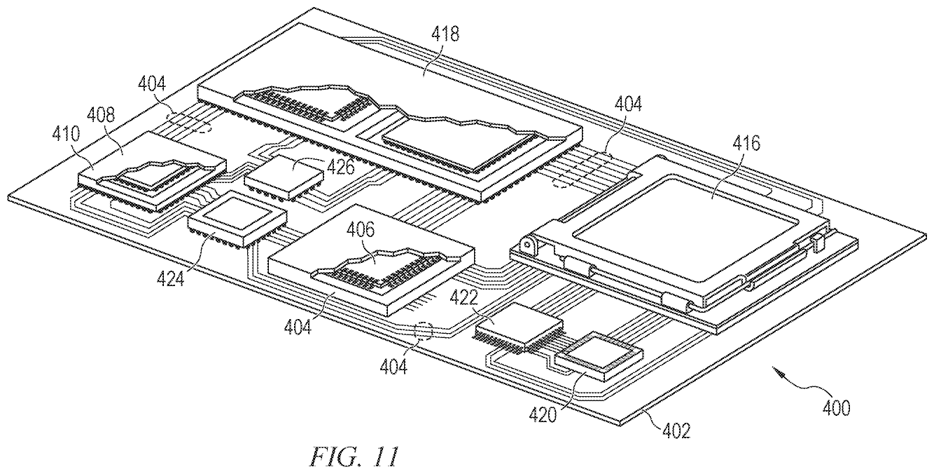

FIG. 10a is a top view of a first embodiment of vias 154a and 154b and vias 182a and 182b formed at least partially around that portion of conductive layer 152 within via 150. In the first embodiment, vias 154a and 154b and vias 182a and 182b are partial arcs or segments on opposite sides of via 150. Vias 154a and 154b and vias 182a and 182b are offset or spaced apart from one another. FIG. 10b is a top view of a second embodiment of vias 154a and 154b and vias 182a and 182b formed at least partially around that portion of conductive layer 152 within via 150. In the second embodiment, via 154a and 154b and vias 182a and 182b are a partial circle around via 150. Vias 154a and 154b and vias 182a and 182b are offset or spaced apart from one another. FIG. 10c is a top view of a third embodiment of vias 154a and 154b and vias 182a and 182b formed at least partially around that portion of conductive layer 152 within via 150. In the third embodiment, vias 154a and 154b and vias 182a and 182b are partial arcs or segments on four sides of via 150. Vias 154a and 154b and vias 182a and 182b are offset or spaced apart from one another. FIG. 10d is a top view of a fourth embodiment of vias 154a and 154b and vias 182a and 182b formed at least partially around that portion of conductive layer 152 within via 150. In the fourth embodiment, vias 154a and 154b and vias 182a and 182b are partial segments around via 150. Vias 154a and 154b and vias 182a and 182b are offset or spaced apart from one another.

WLP 210 has multiple conductive layers 152, 180, and 192 constituting a multi-layer RDL structure. The stress relief vias 154, 182, and 194 reduce or eliminate cracking in the multi-layer RDL caused by stress, delamination, and warpage. The stress relief vias 154a-154b, 182a-182b, and 194a-194b are formed around the conductive vias between each RDL layer, e.g., vias 150, 162, and 186. The stress relief vias 154a-154b, 182a-182b, and 194a-194b can single circular or multi-circular around each inter-RDL via, and by the locations inline or offset in multi-layer RDLs. The offset slots could provide the advantage over the in-line slots for the topology effect to allow more evenness of RDL and PSV layer formations. The inter-layer connecting vias, such as 150, 162, and 186, are likely points of cracking due to stress, delamination, and warpage. Vias 154a-154b, 182a-182b, and 194a-194b result in less metal coverage and more points of stress relief for WLP 210.

FIG. 11 illustrates electrical device 400 having a chip carrier substrate or PCB 402 with a plurality of semiconductor packages disposed on a surface of PCB 402, including WLP 178, 200, and 210. Electrical device 400 can have one type of semiconductor package, or multiple types of semiconductor packages, depending on the application. Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 11, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB. For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a substrate;
a first redistribution layer (RDL) formed over the substrate; and
a second RDL formed over the first RDL with a first conductive via electrically connecting the first RDL and second RDL and a first opening formed in the second RDL around the first conductive via for stress relief.

2. The semiconductor device of claim 1, wherein the first opening formed in the second RDL includes a semi-circle shape.

3. The semiconductor device of claim 1, wherein the first opening formed in the second RDL includes a plurality of semi-circles or segments.

4. The semiconductor device of claim 1, further including a third RDL formed over the second RDL with a second conductive via electrically connecting the second RDL and third RDL and a second opening formed in the third RDL around the second conductive via for stress relief.

5. The semiconductor device of claim 4, wherein the first opening formed in the second RDL is offset from the second opening formed in the third RDL.

6. The semiconductor device of claim 1, further including a plurality of first openings formed in the second RDL around the first conductive via for stress relief, wherein each of the plurality of first openings is offset from one another.

7. A semiconductor device, comprising:
a substrate; and
a first redistribution layer (RDL) formed over the substrate with a first conductive via extending from the first RDL and a first opening formed in the first RDL around the first conductive via for stress relief.

8. The semiconductor device of claim 7, wherein the first opening formed in the first RDL includes a semi-circle shape.

9. The semiconductor device of claim 7, wherein the first opening formed in the first RDL includes a plurality of semi-circles or segments.

10. The semiconductor device of claim 7, further including a second RDL formed over the first RDL with a second conductive via electrically connecting the first RDL and second RDL and a second opening formed in the second RDL around the second conductive via for stress relief.

11. The semiconductor device of claim 10, wherein the first opening formed in the first RDL is offset from the second opening formed in the second RDL.

12. The semiconductor device of claim 10, further including a plurality of second openings formed in the second RDL around the first conductive via for stress relief, wherein each of the plurality of second openings is offset from one another.

13. The semiconductor device of claim 7, further including a plurality of first openings formed in the first RDL around the first conductive via for stress relief, wherein each of the plurality of first openings is offset from one another.

14. A method of making a semiconductor device, comprising:
providing a substrate;
forming a first redistribution layer (RDL) over the substrate;
forming a second RDL over the first RDL with a first conductive via electrically connecting the first RDL and second RDL; and
forming a first opening in the second RDL around the first conductive via for stress relief.

15. The method of claim 14, further including forming the first opening formed in the second RDL as a semi-circle.

16. The method of claim 14, further including forming the first opening formed in the second RDL as a plurality of semi-circles or segments.

17. The method of claim 14, further including:
forming a third RDL over the second RDL with a second conductive via electrically connecting the second RDL and third RDL; and
forming a second opening formed in the third RDL around the second conductive via for stress relief.

18. The method of claim 17, wherein the first opening formed in the second RDL is offset from the second opening formed in the third RDL.

19. The method of claim 14, further including forming a plurality of first openings in the second RDL around the first conductive via for stress relief, wherein each of the plurality of first openings are offset from one another.

20. A method of making a semiconductor device, comprising:
providing a substrate; and
forming a first redistribution layer (RDL) over the substrate with a first conductive via extending from the first RDL and a first opening formed in the first RDL around the first conductive via for stress relief.

21. The method of claim 20, wherein the first opening formed in the first RDL includes a semi-circle shape.

22. The method of claim 20, wherein the first opening formed in the first RDL includes a plurality of semi-circles or segments.

23. The method of claim 20, further including forming a second RDL over the first RDL with a second conductive via electrically connecting the first RDL and second RDL and a second opening formed in the second RDL around the second conductive via for stress relief.

24. The method of claim 23, wherein the first opening formed in the first RDL is offset from the second opening formed in the second RDL.

25. The method of claim 20, further including forming a plurality of first openings in the first RDL around the first conductive via for stress relief, wherein each of the plurality of first openings is offset from one another.
